(19) United States
(12) Patent Application Publication
(10) Pub. No.: US 2026/0255966 A1
(43) Pub. Date: Aug. 27, 2026

(54) SEMICONDUCTOR DEVICE

(71) Applicant: FUJI ELECTRIC CO., LTD., Kanagawa (JP)

(72) Inventors: Toshiaki SAKATA, Matsumoto-city (JP); Yoshihisa SUZUKI, Matsumoto-city (JP); Kodai YAMADA, Matsumoto-city (JP); Taisuke FUJISAWA, Matsumoto-city (JP)

(21) Appl. No.: 19/457,162

(22) Filed: Jan. 23, 2026

(30) Foreign Application Priority Data
Feb. 21, 2025 (JP) 2025-027301

(51) Int. Cl. H10W 40/50; H10D 89/60

(52) U.S. Cl. CPC H10W 40/50; H10D 89/611

(57) ABSTRACT

Provided is a semiconductor device comprising a source electrode that is arranged above an upper surface of a semiconductor substrate and includes a first electrode portion and a second electrode portion, a temperature-sensing diode arranged between the first electrode portion and the second electrode portion and the cathode thereof being connected to the first electrode portion, an anode pad that is arranged between the first electrode portion and the second electrode portion and connected to the anode of the temperature-sensing diode, and an anode-side Zener diode that is arranged between the first electrode portion and the second electrode portion and connected to the anode pad and the second electrode portion.

The contents of the following patent application (s) are incorporated herein by reference: NO. 2025-027301 filed in JP on Feb. 21, 2025.

### BACKGROUND

### 1. Technical Field

The present invention relates to a semiconductor device.

### 2. Related Art

Patent document 1 describes a semiconductor device including a temperature detecting diode.

Patent Document 1: Japanese Patent Application Publication No. 2007-287919

### BRIEF DESCRIPTION OF THE DRAWINGS

FIG. 1 is a top view illustrating an example of a semiconductor device 100 according to one embodiment of the present invention.

FIG. 2 is an enlarged view of a region A in FIG. 1.

FIG. 3 is an enlarged view of a region A in FIG. 1.

FIG. 4 illustrates an arrangement of a contact hole in the region A.

FIG. 5 is a cross-sectional view illustrating an example of an A-A’ line in FIG. 4.

FIG. 6 is a cross-sectional view illustrating an example of a B-B’ line in FIG. 4.

FIG. 7 is a cross-sectional view illustrating an example of a C-C’ line in FIG. 4.

FIG. 8 is a cross-sectional view illustrating an example of a D-D’ line in FIG. 4.

FIG. 9 is a cross-sectional view illustrating an example of E-E’ line in FIG. 4.

FIG. 10 illustrates another example of a cross section C-C’.

FIG. 11 illustrates another example of a region A.

FIG. 12 is a circuit schematic of a semiconductor circuit 500 including the semiconductor device 100.

FIG. 13 illustrates another example of the cross section C-C’.

FIG. 14 is a top view illustrating an example of a semiconductor device 100 according to another embodiment.

FIG. 15 is an enlarged view of a region A in FIG. 14.

FIG. 16 illustrates an example of a cross section C-C’ in FIG. 15.

### DESCRIPTION OF EXEMPLARY EMBODIMENTS

Hereinafter, the present invention will be described through embodiments of the invention, but the following embodiments do not limit the invention according to the claims. In addition, not all of the combinations of features described in the embodiments are essential to the solving means of the invention.

As used herein, one side in a direction parallel to a depth direction of a semiconductor substrate is referred to as “upper” and the other side is referred to as “lower”. One surface of two principal surfaces of a substrate, a layer or other member is referred to as an upper surface, and the other surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. Note that a +Z-axis direction and a -Z-axis direction are directions opposite to each other. When the Z-axis direction is described without describing the signs, it means that the direction is parallel to the +Z axis and the -Z axis.

In the present specification, orthogonal axes parallel to the upper surface and the lower surface of the semiconductor substrate are referred to as the X axis and the Y axis, respectively. In addition, an axis perpendicular to the upper surface and the lower surface of the semiconductor substrate is referred to as the Z axis. In the present specification, the direction of the Z axis may be referred to as a depth direction. In addition, in the present specification, a direction parallel to the upper surface and the lower surface of the semiconductor substrate may be referred to as a horizontal direction, including the X axis and the Y axis.

A region from the center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

When a term such as “same” or “equal” is used herein, it may encompass a case where an error due to a variation in manufacturing or the like is included. The error is, for example, within 10%. Also, when a term such as “parallel” or “perpendicular” is used, an error of 5° or less may be included, for example.

In the present specification, a conductivity type of a doping region where doping has been carried out with an impurity is described as a p type or an n type.

In the present specification, the impurity may particularly mean either a donor of the N type or an acceptor of the P type, and may be described as a dopant.

In the present specification, doping means introducing the donor or the acceptor into the semiconductor substrate and turning it into a semiconductor presenting a conductivity type of the N type, or a semiconductor presenting conductivity type of the P type.

A p+ type or an n+ type described in the present specification means a doping concentration higher than that of the p type or the n type, and a p- type or an n- type described herein means a doping concentration lower than that of the p type or the n type. Further, in the present specification, a description of a P++ type or an N++ type means a higher doping concentration than that of the P+ type or the N+ type. In the present specification, a unit system is the SI base unit system unless otherwise noted. Although a unit of length may be indicated by cm, it may be converted to meters (m) before calculations.

In the present specification, the transistor may be either an FET or a bipolar transistor, unless particularly described. The terms “base”, “source”, and “drain” described in the present specification may be read as “gate”, “emitter”, and “collector”, and the terms “gate”, “emitter”, and “collector” may be read as “base”, “source”, and “drain”.

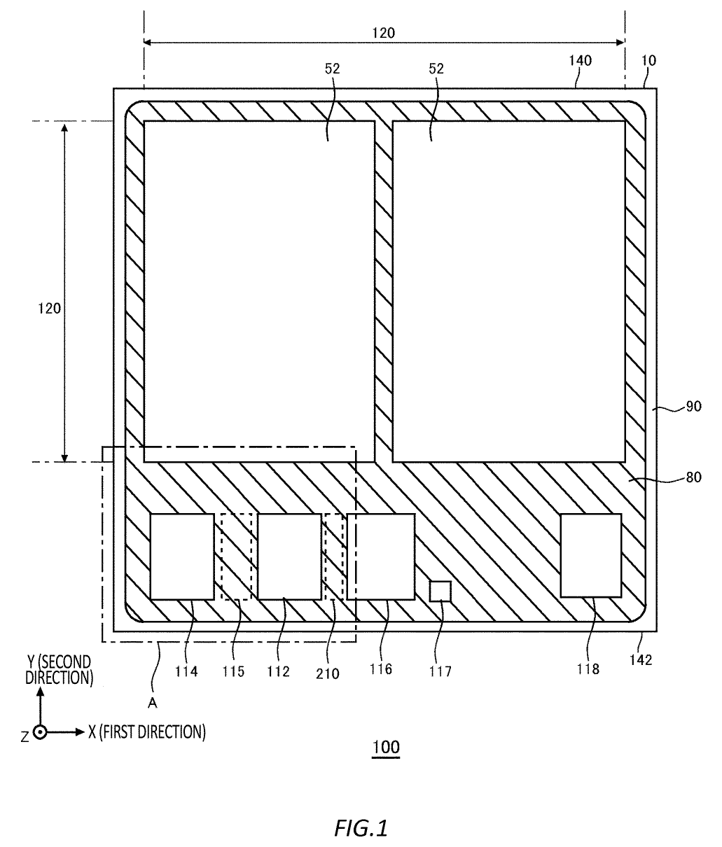

FIG. 1 is a top view illustrating an example of a semiconductor device 100 according to one embodiment of the present invention. FIG. 1 illustrates positions at which respective members are projected on an upper surface of a semiconductor substrate 10. FIG. 1 illustrates merely some of the members of the semiconductor device 100, and omits illustrations of some of the members.

The semiconductor device 100 includes the semiconductor substrate 10. The semiconductor substrate 10 is a substrate formed of a semiconductor material. As an example, the semiconductor substrate 10 is a wide bandgap semiconductor substrate such as a silicon carbide semiconductor substrate, a silicon substrate, or a gallium nitride. End portions of an outer perimeter of the semiconductor substrate 10 when viewed in the top view are referred herein to as outer perimeter ends 140. The phrase "when viewed in the top view" refers to a case where an object is seen in parallel with the Z axis from the upper surface side of the semiconductor substrate 10. In addition, any end side in the outer perimeter ends 140 of the semiconductor substrate 10 when viewed in the top view is referred to as a first end side 142. A direction parallel to the first end side 142 when viewed in the top view is referred to as an X-axis direction, and a direction perpendicular to the first end side 142 is referred to as a Y-axis direction.

The semiconductor substrate 10 is provided with an active portion 120. The active portion 120 is a region through which a main current flows in the depth direction between the upper surface and the lower surface of the semiconductor substrate 10 when the semiconductor device 100 operates. A source electrode 52 is provided above the active portion 120. A region below the source electrode 52 may be the active portion 120. Alternatively, a region where the source electrode 52 and the semiconductor substrate 10 are periodically brought into contact with each other in a region below the source electrode 52 may be the active portion 120. Opposite ends in the X-axis direction of the region where the source electrode 52 and the semiconductor substrate 10 are brought into contact with each other may be opposite ends of the active portion 120 in the X-axis direction. Opposite ends in the Y-axis direction of the region where the source electrode 52 and the semiconductor substrate 10 are brought into contact with each other may be opposite ends of the active portion 120 in the Y-axis direction. The active portion 120 may be a rectangular region defined by the above-described opposite ends in the X-axis direction and the above-described opposite ends in the Y-axis direction.

The active portion 120 may be a region in which a semiconductor element is formed. At least one of a transistor portion including a transistor element such as a MOSFET or a diode portion including a diode element such as a freewheeling diode (FWD) is provided in the active portion 120. Although a MOSFET is provided as the transistor portion in the active portion 120 of the present example, other transistor elements such as an IGBT may be provided.

The semiconductor device 100 may include one or more pads above the upper surface of the semiconductor substrate 10. The semiconductor device 100 of the present example includes an anode pad 112, a cathode pad 114, a gate pad 116, a built-in resistance measurement pad 117, and an auxiliary source pad 118. Note that, an active portion 120 provided with a semiconductor element may be provided at a lower portion of each pad.

The semiconductor device 100 includes a temperature-sensing diode 115. The temperature-sensing diode 115 is arranged above the upper surface of the semiconductor substrate 10. The temperature-sensing diode 115 of the present example is provided outside the active portion 120. The temperature-sensing diode 115 is provided in a region between the anode pad 112 and the cathode pad 114. For example, when the size of the semiconductor device 100 is small, the temperature-sensing diode 115 may be formed between the anode pad 112 and the cathode pad 114, instead of at the center of the semiconductor substrate 10. For example, when the semiconductor substrate 10 is a silicon carbide semiconductor substrate, the semiconductor device 100 may be reduced in size. Providing the temperature-sensing diode 115 at an end portion of the semiconductor substrate 10 can increase a surface area of the active portion 120. The temperature-sensing diode 115 of the present example is a p-n junction diode.

The anode pad 112 is arranged above the upper surface of the semiconductor substrate 10 and connected to the anode of the temperature-sensing diode 115. The cathode pad 114 is arranged above the upper surface of the semiconductor substrate 10 and connected to the cathode of the temperature-sensing diode 115. A temperature of the semiconductor device 100 is measured by causing a predetermined current to flow between the anode pad 112 and the cathode pad 114 and detecting a forward voltage at the temperature-sensing diode 115.

In the present specification, a direction in which the anode pad 112 and the cathode pad 114 are aligned is a first direction. In the top view, a direction that intersects with the first direction is a second direction. The second direction may be orthogonal to the first direction. The first direction of the present example is the X-axis direction, and the second direction is the Y-axis direction. The anode pad 112 and the cathode pad 114 of the present example face the active portion 120 in the second direction. At least a portion of the anode pad 112 and the cathode pad 114 may face the active portion 120 in the second direction.

The semiconductor device 100 includes an anode-side Zener diode 210. The anode-side Zener diode 210 is arranged above the upper surface of the semiconductor substrate 10. The anode-side Zener diode 210 is connected between the anode pad 112 and the source electrode 52. The anode-side Zener diode 210 may have a plurality of diode elements connected in series. Each of the diode elements is connected such that the polarity thereof is alternately inverted. Providing the anode-side Zener diode 210 can stabilize the potential of the anode pad 112. Thus, an ESD withstand capability of the temperature-sensing diode 115 can be improved.

A gate voltage is applied to the gate pad 116. The gate pad 116 of the present example is connected to a gate conductive portion of the transistor portion of the active portion 120 via a gate runner described below.

The semiconductor device 100 may include a current sensing unit that is not shown. The current sensing unit has a same structure as that of the transistor portion, and has a smaller surface area (corresponding to a surface area of a channel) than the transistor portion in a top view. A predetermined current flows through the transistor portion when the semiconductor device 100 is operated, and a current according to the current value at the transistor portion flows through the current sensing unit.

The semiconductor device 100 includes the built-in resistance measurement pad 117. The built-in resistance measurement pad 117 is used to measure a resistance value of a built-in gate resistor (not shown) provided between the gate pad 116 and the built-in resistance measurement pad 117 before product shipment. The built-in resistance measurement pad 117 is arranged near the gate pad 116 on a path of a metal runner 131 (gate runner 130) and directly connected to the metal runner 131. Note that, the semiconductor device 100 may not include the built-in resistance measurement pad 117. The semiconductor device 100 includes the auxiliary source pad 118 connected to the source electrode 52. The source electrode 52 and the auxiliary source pad 118 may be a single electrode provided continuously. An active portion 120 provided with a semiconductor element is provided at a lower portion of the auxiliary source pad 118. Note that, the semiconductor device 100 may not include the auxiliary source pad 118.

Each pad is formed of a metal material such as aluminum. The plurality of pads are arrayed in a predetermined direction between the active portion 120 and the first end side 142 in the upper surface of the semiconductor substrate 10. Note that, the number and types of the pads provided in the semiconductor substrate 10 are not limited to the example illustrated in FIG. 1.

A protective film 80 such as polyimide is provided above the upper surface of the semiconductor substrate 10. The protective film 80 may cover a portion of the source electrode 52 and each pad. An aperture that exposes the source electrode 52 and each pad to the above is provided in the protective film 80. The source electrode 52 and each pad are wire-bonded and connected to an external circuit at the aperture. In FIG. 1, the protective film 80 is shown with hatching.

An edge termination structure portion 90 is provided between the active portion 120 and each pad and the outer perimeter end 140 of the semiconductor substrate 10 in the upper surface of the semiconductor substrate 10. The edge termination structure portion 90 may be circularly arranged so as to surround the active portion 120 and each pad in the upper surface of the semiconductor substrate 10. The edge termination structure portion 90 of the present example is arranged along the outer perimeter ends 140 of the semiconductor substrate 10. The edge termination structure portion 90 reduces an electric field strength on the upper surface side of the semiconductor substrate 10. The edge termination structure portion 90 includes, for example, a guard ring, a field plate, a RESURF and a combination structure of them.

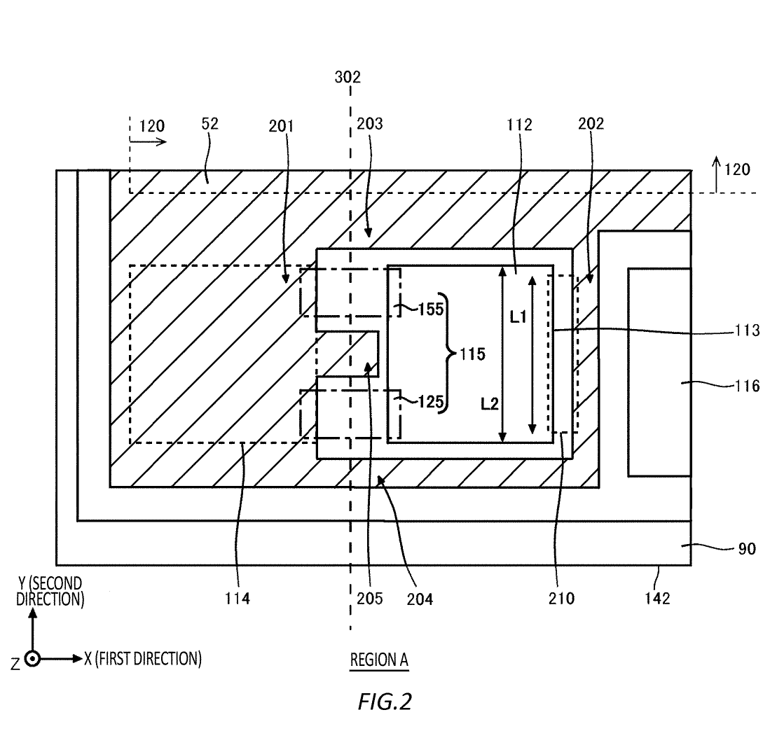

FIG. 2 is an enlarged view of a region A in FIG. 1. The region A is a region around the anode pad 112 and the cathode pad 114. Note that, in FIG. 2, illustration of the protective film 80 and the like is omitted. In addition, the source electrode 52 is shown with diagonal hatching. The cathode pad 114 of the present example is a part of the source electrode 52. Among the source electrode 52, a region on an opposite side from the anode pad 112 relative to the temperature-sensing diode 115 may be treated as the cathode pad 114.

For example, a straight line that passes through the center of the temperature-sensing diode 115 in the X-axis direction that is parallel to the Y axis is a straight line 302. A region that is linearly symmetrical with the anode pad 112 relative to the straight line 302 may be treated as the cathode pad 114. In a region on an opposite side from the anode pad 112 relative to the temperature-sensing diode 115, the source electrode 52 that is exposed at the aperture provided in the protective film 80 may be treated as the cathode pad 114. Note that, the region of the cathode pad 114 may be covered by the protective film 80.

The temperature-sensing diode 115 of the present example is provided in a region between the anode pad 112 and the cathode pad 114. The temperature-sensing diode 115 of the present example has a main diode 155 and a protection diode 125. An anode of the main diode 155 is connected to the anode pad 112, and a cathode of the main diode 155 is connected to the cathode pad 114. The forward voltage at the temperature-sensing diode 115 may be a forward voltage at the main diode 155.

The direction of the p-n junction of the protection diode 125 is opposite to that of the temperature-sensing diode 115. That is, a cathode of the protection diode 125 is connected to the anode pad 112, and an anode of the protection diode 125 is connected to the cathode pad 114. By including the protection diode 125, the main diode 155 can be protected even when an opposite voltage is applied to the anode pad 112 and the cathode pad 114.

Both of the main diode 155 and the protection diode 125 may be provided between the anode pad 112 and the cathode pad 114. Note that, the temperature-sensing diode 115 may not include the protection diode 125.

The source electrode 52 is arranged above the upper surface of the semiconductor substrate 10. An interlayer dielectric film is provided between the source electrode 52 and the semiconductor substrate 10, but an illustration thereof is omitted in FIG. 2. The source electrode 52 may be connected to the semiconductor substrate 10 via a contact hole formed in the interlayer dielectric film.

The source electrode 52 of the present example includes a first electrode portion 201, a second electrode portion 202, a third electrode portion 203, a fourth electrode portion 204, and a fifth electrode portion 205. The first electrode portion 201 and the second electrode portion 202 are arranged across the temperature-sensing diode 115. The first electrode portion 201 and the second electrode portion 202 of the present example are arranged side by side in the X-axis direction. The temperature-sensing diode 115 is arranged between the first electrode portion 201 and the second electrode portion 202 above the upper surface of the semiconductor substrate 10. That is, the first electrode portion 201, the temperature-sensing diode 115, and the second electrode portion 202 of the present example are arranged side by side in the X-axis direction.

The anode pad 112 is arranged between the first electrode portion 201 and the second electrode portion 202 above the upper surface of the semiconductor substrate 10. In the present example, the temperature-sensing diode 115 is arranged between the first electrode portion 201 and the anode pad 112 in the X-axis direction. Opposite ends of the temperature-sensing diode 115 in the X-axis direction may be overlapped with the first electrode portion 201 or the anode pad 112.

The cathode of the main diode 155 is connected to the first electrode portion 201. The anode of the main diode 155 is connected to the anode pad 112. In the present specification, the cathode of the main diode 155 may be treated as the cathode of the temperature-sensing diode 115. Similarly, the anode of the main diode 155 may be treated as the anode of the temperature-sensing diode 115. The anode of the protection diode 125 is connected to the first electrode portion 201. The cathode of the protection diode 125 is connected to the anode pad 112.

An anode-side Zener diode 210 is provided between the anode pad 112 and the second electrode portion 202. The anode-side Zener diode 210 is arranged between the first electrode portion 201 and the second electrode portion 202 above the upper surface of the semiconductor substrate 10. The anode-side Zener diode 210 of the present example is arranged between the anode pad 112 and the second electrode portion 202 in the X-axis direction. Opposite ends of the anode-side Zener diode 210 in the X-axis direction may be overlapped with the anode pad 112 or the second electrode portion 202. The anode-side Zener diode 210 is connected to the anode pad 112 and the second electrode portion 202.

The first electrode portion 201 of the present example is a region that faces the temperature-sensing diode 115 on an opposite side of the source electrode 52 from the anode pad 112. An end portion position of the first electrode portion 201 in the Y-axis direction may be the same as an end portion position of the temperature-sensing diode 115 in the Y-axis direction. The end portion position of the first electrode portion 201 in the X-axis direction may be the same as the end portion position of the source electrode 52. The first electrode portion 201 may be a region that is the same as the cathode pad 114.

The second electrode portion 202 of the present example is a region that faces the anode pad 112 on an opposite side of the source electrode 52 from the temperature-sensing diode 115. The second electrode portion 202 may be arranged between the anode pad 112 and the gate pad 116 in the X-axis direction. The end portion position of the second electrode portion 202 in the Y-axis direction may the same as the end portion position of the anode pad 112 in the Y-axis direction. The second electrode portion 202 may refer to the entire stripe portion extending in the Y-axis direction between the anode pad 112 and the gate pad 116, among the source electrode 52. The end portion position of the second electrode portion 202 in the X-axis direction may be the same as the end portion position of the source electrode 52.

The third electrode portion 203 and the fourth electrode portion 204 are arranged across the temperature-sensing diode 115 in the Y-axis direction. That is, the third electrode portion 203, the temperature-sensing diode 115, and the fourth electrode portion 204 of the present example are arranged side by side in the Y-axis direction.

The third electrode portion 203 of the present example is a region arranged between the temperature-sensing diode 115 and the active portion 120 among the source electrode 52. The end portion position of the third electrode portion 203 in the Y-axis direction on the temperature-sensing diode 115 side may be the same as the end portion position of the source electrode 52. The end portion position of the third electrode portion 203 in the Y-axis direction on the active portion 120 side may be the same as the end portion position of the gate runner 130 described below. Among the source electrode 52, the region that is overlapped with the gate runner 130 may or may not be included in the third electrode portion 203. The end portion position of the third electrode portion 203 in the X-axis direction may be the same as the end portion position of the temperature-sensing diode 115. Among the source electrode 52, a region that faces the anode pad 112 and a region that faces the cathode pad 114 in the Y-axis direction may also be included in the third electrode portion 203.

The fourth electrode portion 204 of the present example is a region that faces the temperature-sensing diode 115 in the Y-axis direction on an opposite side of the source electrode 52 from the active portion 120. The end portion position of the fourth electrode portion 204 in the Y-axis direction may be the same as the end portion position of the source electrode 52. The end portion position of the fourth electrode portion 204 in the X-axis direction may be the same as the end portion position of the temperature-sensing diode 115. Among the source electrode 52, a region that faces the anode pad 112 and a region that faces the cathode pad 114 in the Y-axis direction may also be included in the fourth electrode portion 204.

The fifth electrode portion 205 of the present example is a region provided between the main diode 155 and the protection diode 125, among the source electrode 52. The fifth electrode portion 205 may be a region provided to project from the first electrode portion 201 in the X-axis direction. The end portion position of the fifth electrode portion 205 in the Y-axis direction may be the same as the end portion position of the source electrode 52. The end portion position of the fifth electrode portion 205 in the X-axis direction may be the same as the end portion position of the source electrode 52.

The anode-side Zener diode 210 may be provided to extend in the Y-axis direction. That is, a length in the Y-axis direction of the anode-side Zener diode 210 may be greater than the width in the X-axis direction. The anode-side Zener diode 210 includes one or more p-type portions and one or more n-type portions that form a plurality of p-n junctions. Each of the p-type portions and the n-type portions may have a stripe shape that extends in the Y-axis direction. The p-n junction portion may be arranged along the Y-axis direction.

At the anode pad 112, an end side that faces the second electrode portion 202 is a first end side 113. The first end side 113 of the present example is a side that is parallel to the Y axis. A length L1 of the anode-side Zener diode 210 in the Y-axis direction is 25% or more and 100% or less of a length L2 of the first end side 113 in the Y-axis direction. The length L1 may be 50% or more or may be 75% or more of the length L2. The length L1 may be 300 μm or more, may be 400 μm or more, or may be 500 μm or more.

The length L1 of the anode-side Zener diode 210 may be a length of the p-n junction portion in the top view. Providing an anode-side Zener diode 210 that extends in the Y-axis direction can improve the ESD withstand capability. In addition, by adjusting the length L1 of the anode-side Zener diode 210, the ESD withstand capability can be adjusted. In the anode-side Zener diode 210, the p-type portion and the n-type portion are alternately arranged along the X-axis direction, and the p-n junction portion is periodically arranged in the X-axis direction. The ESD withstand capability can be adjusted also by adjusting the number of steps of the p-n junction portion of the anode-side Zener diode 210.

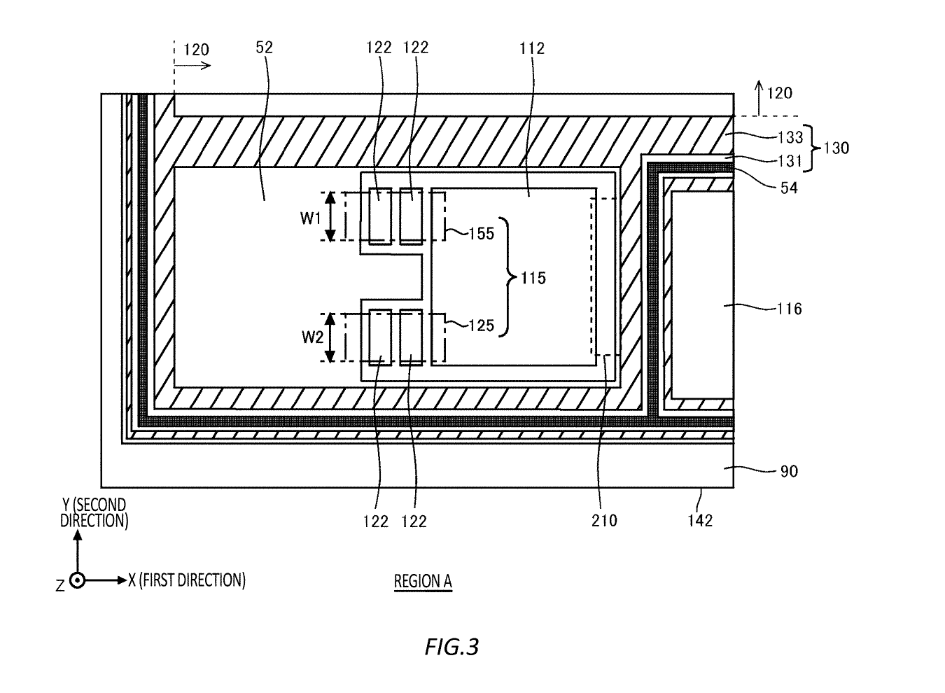

FIG. 3 is an enlarged view of a region A in FIG. 1. In FIG. 3, an arrangement of the gate runner 130, the anode-side Zener diode 210, the temperature-sensing diode 115, the connection metal 122, the source electrode 52, the anode pad 112, the gate pad 116, the contact hole 54, the edge termination structure portion 90 and the like in the region A is illustrated.

The connection metal 122 may be provided above the main diode 155. The connection metal 122 connects the multi-stage p-n junction of the main diode 155 in series. The connection metal 122 may also be provided above the protection diode 125.

In the Y-axis direction, a length W1 of the main diode 155 may be greater than a length W2 of the protection diode 125. In this manner, the surface areas of the anode pad 112 and the temperature-sensing diode 115 can be reduced even when the protection diode 125 is provided. The length W1 may be 1.5 times or more of the length W2, or may be twice or more thereof.

The gate runner 130 is arranged above the upper surface of the semiconductor substrate 10. The gate runner 130 is connected to the gate pad 116. The gate runner 130 is provided so as to surround the active portion 120 and each pad along the edge termination structure portion 90. In addition, the gate runner 130 of the present example is also provided between the anode pad 112 and the cathode pad 114 (see FIG. 2) and the active portion 120. That is, the gate runner 130 of the present example surrounds the temperature-sensing diode 115, the anode pad 112, and the cathode pad 114 in the top view. The gate runner 130 may surround the source electrode 52, the first electrode portion 201, the second electrode portion 202, the third electrode portion 203, the fourth electrode portion 204, and the fifth electrode portion 205 illustrated in FIG. 2. The gate runner 130 may surround the anode-side Zener diode 210.

The gate runner 130 includes a poly runner 133 and a metal runner 131. The poly runner 133 is a polysilicon gate runner 130, and the metal runner 131 is a metal gate runner 130.

The poly runner 133 is arranged so as to surround the anode pad 112, the cathode pad 114, and the active portion 120 from below the gate pad 116. The metal runner 131 includes a portion that is arranged along the edge termination structure portion 90 of the semiconductor substrate 10 and a portion that is arranged so as to surround the gate pad 116. In the present example, no metal runner 131 is provided between the anode pad 112 and the cathode pad 114 and the active portion 120, but the poly runner 133 is provided therebetween. In FIG. 3, the poly runner 133 is shown with a coarse hatching.

The metal runner 131 is formed above the poly runner 133. The interlayer dielectric film 38 is formed between the metal runner 131 and the poly runner 133. The contact hole 54 is formed in the interlayer dielectric film 38, and the metal runner 131 and the poly runner 133 are connected via the contact hole 54. In FIG. 3, the contact hole 54 is shown with a dark hatching. In a direction perpendicular to the extending direction of the gate runner 130, a width of the metal runner 131 may be smaller than that of the poly runner 133.

In the present example, the entire region between the anode pad 112 and the source electrode 52 is not overlapped with the gate runner 130. The region between the anode pad 112 and the source electrode 52 may be the region sandwiched by the anode pad 112 and the source electrode 52, or may be the region that overlaps with any straight line connecting the anode pad 112 and the source electrode 52. In this manner, a short circuit between the anode pad 112 and the source electrode 52 due to a level difference in the gate runner 130 can be suppressed. In the present example, the entire region between the anode pad 112 and the source electrode 52 is not overlapped with the poly runner 133. In addition, said region is not overlapped with the metal runner 131.

The connection metal 122 may be provided in a region between the anode pad 112 and the source electrode 52. The entire region between the anode pad 112 and the connection metal 122 may not be overlapped with the gate runner 130. In addition, the entire region between the source electrode 52 and the connection metal 122 may not be overlapped with the gate runner 130. In addition, the entire region between the connection metals 122 may not be overlapped with the gate runner 130. The entire region of the connection metal 122 may not be overlapped with the poly runner 133.

The anode pad 112 may not be overlapped with the gate runner 130. The anode pad 112 of the present example is surrounded by the gate runner 130 and is not connected to the gate runner 130. The connection metal 122 may also not be overlapped with the gate runner 130.

The distance between the anode pad 112 and the source electrode 52 may be 50 μm or less, may be 40 μm or less, or may be 30 μm or less. Said distance may be 5 μm or more. Said distance in the present example is 15 μm or more and 20 μm or less. Said distance may be the distance between the anode pad 112 and the source electrode 52 at a position closest to the gate runner 130. Said distance may be the shortest distance between the anode pad 112 and the source electrode 52. When the connection metal 122 is provided between the anode pad 112 and the source electrode 52, the description related to said distance can be applied to any of the distance between the anode pad 112 and the connection metal 122, the distance between the source electrode 52 and the connection metal 122, and the distance between the connection metals 122.

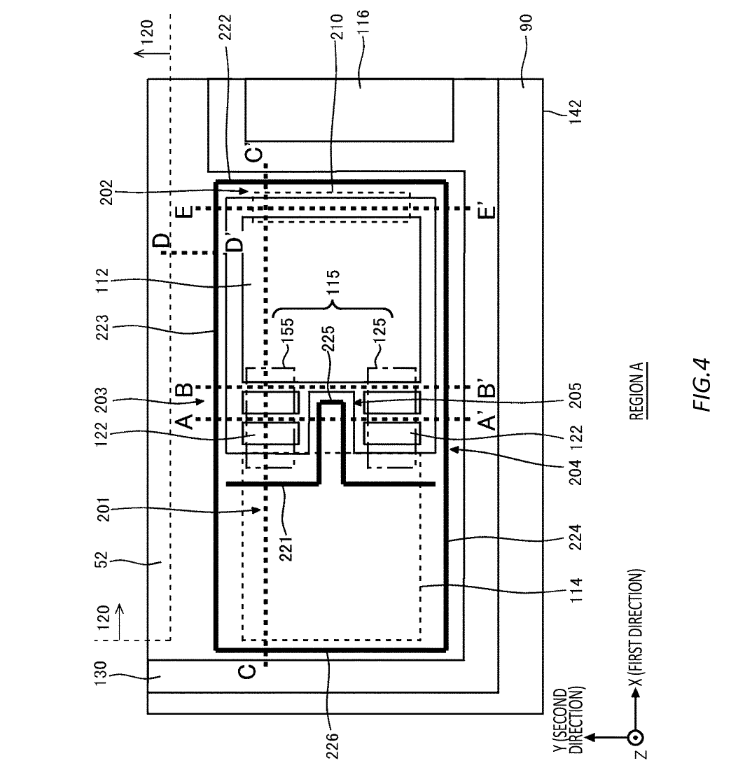

FIG. 4 illustrates an arrangement of the contact hole in the region A. Also in FIG. 4, illustration of some configuration of the protective film 80 or the like is omitted. The contact hole of the present example is provided in the interlayer dielectric film, and connect the source electrode 52 and the semiconductor substrate 10. The contact hole of the present example includes a first hole portion 221, a second hole portion 222, a third hole portion 223, a fourth hole portion 224, a fifth hole portion 225, and a sixth hole portion 226. Any portion of the contact hole may be arranged further inside relative to the gate runner 130. The inside refers to a side close to the temperature-sensing diode 115.

The first hole portion 221 connects the first electrode portion 201 and the semiconductor substrate 10. At least a portion of the first hole portion 221 is provided to extend in the Y-axis direction. At least a portion of the first hole portion 221 is arranged to face the temperature-sensing diode 115 in the X-axis direction. The first hole portion 221 may be provided to extend in the Y-axis direction for half or more of a width of the temperature-sensing diode 115 (for example, W1+W2 in FIG. 3).

The first hole portion 221 may be provided to extend in the Y-axis direction in a range where it faces the main diode 155 in at least the X-axis direction. That is, the first hole portion 221 may be provided throughout a range within the width W1 or more at a position facing the main diode 155. The first hole portion 221 may be provided to extend in the Y-axis direction also in a range where it faces the protection diode 125 in the X-axis direction. That is, the first hole portion 221 may be provided throughout a range within the width W2 or more at a position facing the protection diode 125. The first hole portion 221 may be provided to extend in the Y-axis direction in a range where it faces the connection metal 122 in at least the X-axis direction. The first hole portion 221 may be provided to extend to the outside relative to the connection metal 122 in the Y-axis direction.

The first hole portion 221 may be provided near the temperature-sensing diode 115 in the X-axis direction. For example, the distance between the first hole portion 221 and the temperature-sensing diode 115 in the X-axis direction may be 20 μm or less, or may be 10 μm or less. The distance between the first hole portion 221 and the temperature-sensing diode 115 in the X-axis direction may be equal to or smaller than the width W1 (see FIG. 3) of the main diode 155 in the Y-axis direction, may be equal to or smaller than half of the width W1, or may be equal to or smaller than 1/4 of the width W1.

A metal material with the same potential as the source electrode 52 or the source electrode 52 is filled inside each hole portion of the contact hole. Providing the first hole portion 221 can suppress a potential increase below the temperature-sensing diode 115 or the like to suppress the displacement current from flowing from the gate runner 130 toward below the temperature-sensing diode 115 or the like. In this manner, displacement current crowding at the end portion of the gate runner 130 can be suppressed to suppress dvdt breakdown at the end portion of the gate runner 130.

The second hole portion 222 connects the second electrode portion 202 and the semiconductor substrate 10. At least a portion of the second hole portion 222 is provided to extend in the Y-axis direction. At least a portion of the second hole portion 222 is arranged to face the anode-side Zener diode 210 in the X-axis direction. The second hole portion 222 may be provided to extend in the Y-axis direction throughout half or more of the length L1 of the anode-side Zener diode 210. The second hole portion 222 may be provided to extend in the Y-axis direction throughout a range that is longer than the length L1 of the anode-side Zener diode 210.

Providing the second hole portion 222 can suppress potential increase below the anode-side Zener diode 210 and the anode pad 112 or the like to suppress the displacement current from flowing from the gate runner 130 to below the anode-side Zener diode 210 and the anode pad 112 or the like. In this manner, displacement current crowding at the end portion of the gate runner 130 can be suppressed to suppress dvdt breakdown at the end portion of the gate runner 130.

The third hole portion 223 connects the third electrode portion 203 and the semiconductor substrate 10. At least a portion of the third hole portion 223 is provided to extend in the X-axis direction. At least a portion of the third hole portion 223 is arranged to face the temperature-sensing diode 115 and the anode pad 112 in the Y-axis direction. At least a portion of the third hole portion 223 may be arranged to face the cathode pad 114, the temperature-sensing diode 115, and the anode pad 112 in the Y-axis direction. An end portion of the third hole portion 223 may be connected to the end portion of the second hole portion 222.

Providing the third hole portion 223 can suppress potential increase below the temperature-sensing diode 115 and the anode pad 112 or the like to suppress the displacement current from flowing from the gate runner 130 toward below the temperature-sensing diode 115 and the anode pad 112 or the like. In this manner, displacement current crowding at the end portion of the gate runner 130 can be suppressed to suppress dvdt breakdown at the end portion of the gate runner 130.

The fourth hole portion 224 connects the fourth electrode portion 204 and the semiconductor substrate 10. At least a portion of the fourth hole portion 224 is provided to extend in the X-axis direction. At least a portion of the fourth hole portion 224 is arranged to face the temperature-sensing diode 115 and the anode pad 112 in the Y-axis direction. At least a portion of the fourth hole portion 224 may be arranged to face the cathode pad 114, the temperature-sensing diode 115, and the anode pad 112 in the Y-axis direction. An end portion of the fourth hole portion 224 may be connected to the end portion of the second hole portion 222.

Providing the fourth hole portion 224 can suppress potential increase below the temperature-sensing diode 115 and the anode pad 112 or the like to suppress displacement current from flowing from the gate runner 130 toward below the temperature-sensing diode 115 and the anode pad 112 or the like. In this manner, displacement current crowding at the end portion of the gate runner 130 can be suppressed to suppress dvdt breakdown at the end portion of the gate runner 130.

The sixth hole portion 226 connects the source electrode 52 and the semiconductor substrate 10. At least a portion of the sixth hole portion 226 is provided to extend in the Y-axis direction. At least a portion of the sixth hole portion 226 is arranged to face the temperature-sensing diode 115 in the X-axis direction. The sixth hole portion 226 may be provided to extend in the Y-axis direction over half or more of the width (for example, W1+W2 in FIG. 3) of the temperature-sensing diode 115.

The sixth hole portion 226 may be provided to extend in the Y-axis direction in a range where it faces the anode pad 112 in at least the X-axis direction. That is, the sixth hole portion 226 may be provided over a range of the length L2 (see FIG. 2) or more at a position where it faces the anode pad 112.

The sixth hole portion 226 is arranged apart from the temperature-sensing diode 115 relative to the first hole portion 221. The sixth hole portion 226 may be arranged outside the cathode pad 114 among the source electrode 52. Outside refers to a side further away from the temperature-sensing diode 115. The sixth hole portion 226 may be arranged between the cathode pad 114 and the gate runner 130.

Providing the sixth hole portion 226 can suppress potential increase below the cathode pad 114 or the like to suppress the displacement current from flowing from the gate runner 130 toward below the cathode pad 114 or the like. In this manner, displacement current crowding at the end portion of the gate runner 130 can be suppressed to suppress dvdt breakdown at the end portion of the gate runner 130.

One end portion of the sixth hole portion 226 may be connected to the end portion of the third hole portion 223. The other end portion of the sixth hole portion 226 may be connected to an end portion of the fourth hole portion 224. The second hole portion 222, the third hole portion 223, the fourth hole portion 224, and the sixth hole portion 226 may surround the temperature-sensing diode 115 and the anode-side Zener diode 210. The second hole portion 222, the third hole portion 223, the fourth hole portion 224, and the sixth hole portion 226 of the present example surround the temperature-sensing diode 115, the anode pad 112, and the anode-side Zener diode 210. The second hole portion 222, the third hole portion 223, the fourth hole portion 224, and the sixth hole portion 226 may further surround the cathode pad 114. By surrounding the temperature-sensing diode 115 or the like with the contact hole, displacement current that flows from the gate runner 130 toward below the temperature-sensing diode 115 or the like can be suppressed, and dvdt breakdown at the end portion of the gate runner 130 can be suppressed.

The fifth hole portion 225 connects the fifth electrode portion 205 and the semiconductor substrate 10. At least a portion of the fifth hole portion 225 is provided to extend in the Y-axis direction. At least of a portion of the fifth hole portion 225 may be provided to extend in the Y-axis direction along an end side at the edge of the fifth electrode portion 205 in the X-axis direction. The portion of the fifth hole portion 225 may be provided for half or more of a length of said end side of the fifth electrode portion 205 in the Y-axis direction.

Another portion of the fifth hole portion 225 may be provided to extend in the X-axis direction. The portion of the fifth hole portion 225 may be provided for a half or more of the length of the fifth electrode portion 205 in the X-axis direction. The fifth hole portion 225 may have two portions that extend in the X-axis direction. The fifth hole portion 225 of the present example has two portions that extend in the X-axis direction that are connected to each end portion of the portion that extends in the Y-axis direction. The end portion of the portion in the fifth hole portion 225 that extends in the X-axis direction may be connected to the end portion of the first hole portion 221.

Providing the fifth hole portion 225 can suppress the displacement current that passes between the main diode 155 and the protection diode 125. Thus, dvdt breakdown at the end portion of the gate runner 130 can be suppressed.

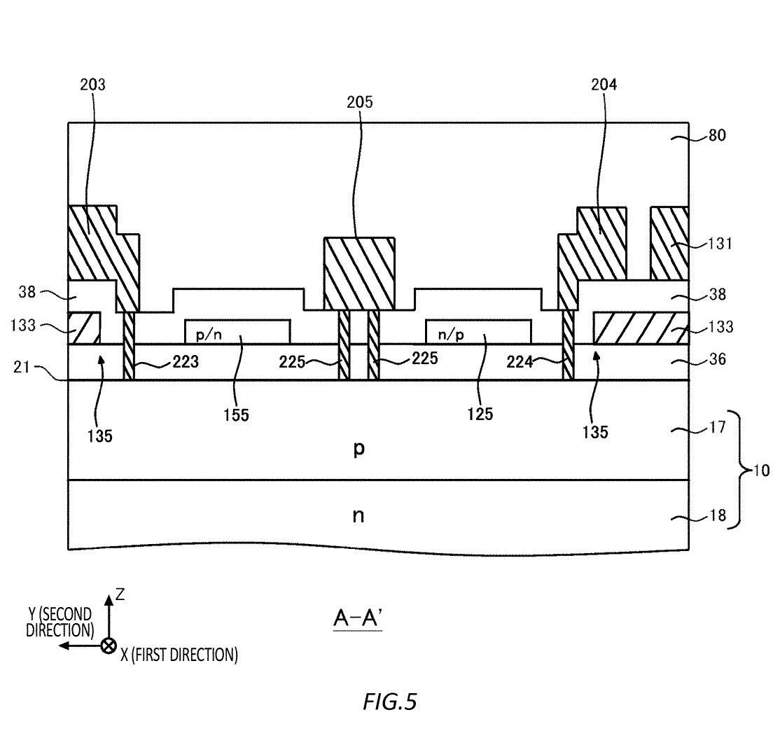

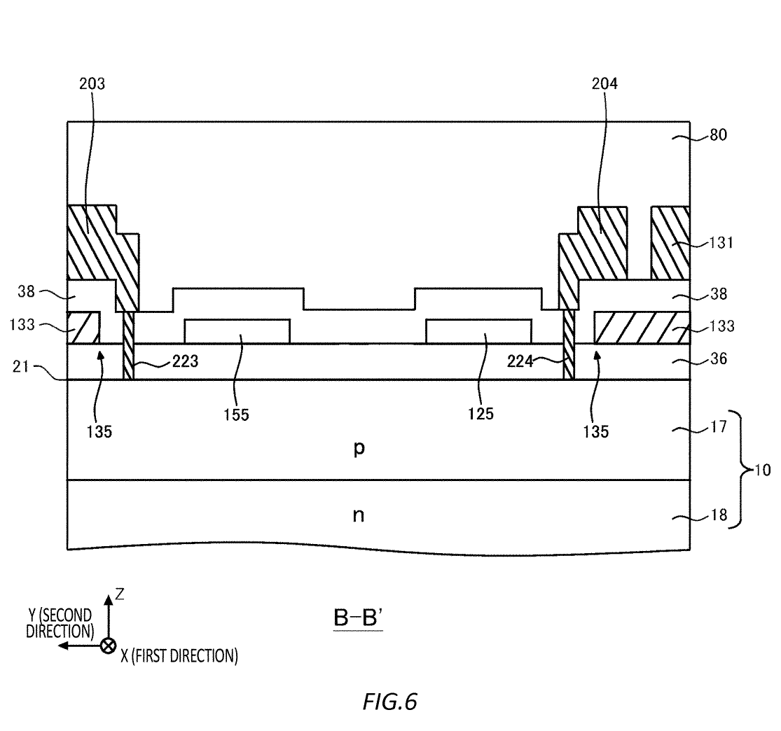

FIG. 5 is a cross-sectional view illustrating an example of an A-A’ line in FIG. 4. The A-A’ cross section is a YZ cross section that passes through the main diode 155 and the protection diode 125. Note that, in FIG. 6, the illustration of a lower surface side of the semiconductor substrate 10 is omitted. In the A-A’ cross section, the semiconductor device 100 includes the semiconductor substrate 10, a field oxide film 36, the main diode 155, the protection diode 125, the poly runner 133, the metal runner 131, the interlayer dielectric film 38, the third electrode portion 203, the fourth electrode portion 204, the fifth electrode portion 205, and the protective film 80. In the present example, the third electrode portion 203, the fourth electrode portion 204, the fifth electrode portion 205 may be collectively referred to as the source electrode 52.

The semiconductor substrate 10 of the present example has an n-type drift region 18 and a p-type well region 17 provided between the drift region 18 and the upper surface 21. Note that, an n-type region may be provided in a portion where it is in contact with the upper surface 21 of the semiconductor substrate 10. A thickness of the semiconductor substrate 10 may be 50 μm or more and 500 μm or less. The thickness of the semiconductor substrate 10 may be 200 μm or less, or may be 100 μm or less.

The field oxide film 36 is provided on the upper surface 21 of the semiconductor substrate 10. The main diode 155, the protection diode 125, the source electrode 52, and the poly runner 133 or the like are provided above the field oxide film 36, and are insulated from the semiconductor substrate 10. The source electrode 52 and the anode pad 112 are also provided above the field oxide film 36 in another cross section. A thickness of the field oxide film 36 may be 0.1 μm or more and 2.0 μm or less.

The interlayer dielectric film 38 is provided above the upper surface 21 of the semiconductor substrate 10. The interlayer dielectric film 38 of the present example is provided above the field oxide film 36, the poly runner 133, the main diode 155, and the protection diode 125. A thickness of the interlayer dielectric film 38 may be 0.1 μm or more and 2.0 μm or less. The interlayer dielectric film 38 may be formed of BPSG or PSG. A thickness of the poly runner 133 may be 0.3 μm or more and 1.3 μm or less.

The source electrode 52 and the metal runner 131 are provided above the interlayer dielectric film 38. The third electrode portion 203 and the fourth electrode portion 204 are provided up to near the main diode 155 and the protection diode 125 than the poly runner 133 in the Y-axis direction. The thicknesses of the source electrode 52 and the metal runner 131 may be 3 μm or more and 7 μm or less. The protective film 80 is provided above the interlayer dielectric film 38, the source electrode 52, and the metal runner 131.

The third hole portion 223 of the present example penetrates through the interlayer dielectric film 38 and the field oxide film 36, and connects the third electrode portion 203 and the semiconductor substrate 10. A metal material such as an aluminum alloy or tungsten may be filled inside the third hole portion 223.

The third hole portion 223 is provided between the poly runner 133 and the main diode 155. Providing the third hole portion 223 can prevent the displacement current from flowing in the interlayer dielectric film 38 or the field oxide film 36 in the direction from the poly runner 133 to the main diode 155. In this manner, displacement current crowding at the end portion 135 of the poly runner 133, which causes the dvdt breakdown to occur, can be suppressed.

The fourth hole portion 224 of the present example penetrates through the interlayer dielectric film 38 and the field oxide film 36, and connects the fourth electrode portion 204 and the semiconductor substrate 10. A metal material such as an aluminum alloy or tungsten may be filled inside the fourth hole portion 224.

The fourth hole portion 224 is provided between the poly runner 133 and the protection diode 125. Providing the fourth hole portion 224 can prevent a displacement current from flowing in the interlayer dielectric film 38 or the field oxide film 36 in the direction from the poly runner 133 to the protection diode 125. In this manner, displacement current crowding at the end portion 135 of the poly runner 133, which causes the dvdt breakdown to occur, can be suppressed.

As described above, the main diode 155 and the protection diode 125 is arranged between the third hole portion 223 and the fourth hole portion 224 in the Y-axis direction. In this manner, the displacement current from the poly runner 133 toward the temperature-sensing diode 115 can be suppressed.

The fifth hole portion 225 of the present example penetrates the interlayer dielectric film 38 and the field oxide film 36, and connects the fifth electrode portion 205 and the semiconductor substrate 10. A metal material such as an aluminum alloy or tungsten may be filled inside the fifth hole portion 225.

The fifth hole portion 225 of the present example is provided between the main diode 155 and the protection diode 125. Providing the fifth hole portion 225 can prevent the displacement current from flowing between the main diode 155 and the protection diode 125 along the X-axis direction. In this manner, displacement current crowding at the end portion of the poly runner 133, which causes the dvdt breakdown to occur, can be suppressed.

FIG. 6 is a cross-sectional view illustrating an example of a B-B’ line in FIG. 4. The B-B’ cross section is a YZ cross section that passes through the main diode 155 and the protection diode 125. Note that, in FIG. 6, the illustration of a lower surface side of the semiconductor substrate 10 is omitted. The B-B’ cross section does not pass through the fifth electrode portion 205. Thus, the structure illustrated in FIG. 6 does not include the fifth electrode portion 205. Other structures are similar to those in the A-A’ cross section.

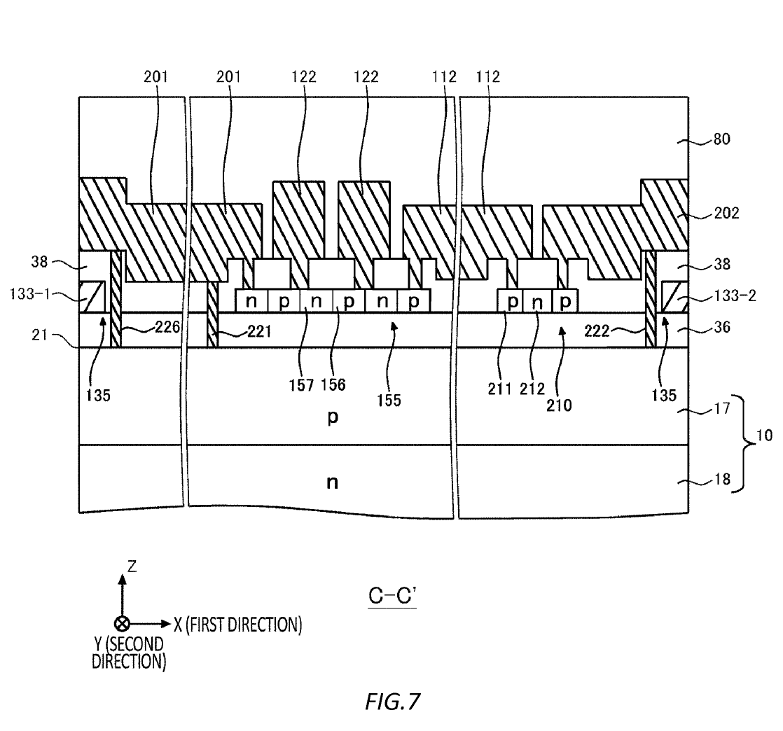

FIG. 7 is a cross-sectional view illustrating an example of a C-C’ line in FIG. 4. The C-C’ cross section is a XZ cross section that passes through the main diode 155 and the anode-side Zener diode 210. Note that, in FIG. 7, the illustration of a lower surface side of the semiconductor substrate 10 is omitted. The configuration below the field oxide film 36 are similar to that in FIG. 5, and therefore description thereof is omitted.

The anode pad 112, the first electrode portion 201, the second electrode portion 202, and the connection metal 122 are connected to the main diode 155 via the contact hole provided in the interlayer dielectric film 38. In the present example, the first electrode portion 201 and the second electrode portion 202 may be collectively referred to as the source electrode 52. In the C-C’ cross section of the present example, the first electrode portion 201, the connection metal 122, the anode pad 112, and the second electrode portion 202 are arranged side by side in order along the first direction.

The main diode 155 of the present example has one or more p-type regions 156 and one or more n-type regions 157 that extend in the Y-axis direction. The p-type region 156 and the n-type region 157 may be polysilicon to which impurities are added. One p-type region 156 may have a greater length in the Y-axis direction he width in the X-axis direction. One n-type region 157 may have a greater length in the Y-axis direction than the width in the X-axis direction. The p-type regions 156 and the n-type regions 157 are alternately arranged along the X-axis direction. The n-type region 157 arranged at one end in the X-axis direction is connected to the first electrode portion 201. The p-type region 156 arranged at the other end in the X-axis direction is connected to the anode pad 112. The main diode 155 of the present example has three p-n junctions between the anode pad 112 and the first electrode portion 201. The connection metal 122 connects adjacent p-n junctions in series. The protection diode 125 also has a structure that is similar to that of the main diode 155. Note that, in the protection diode 125, the p-type regions 156 and the n-type regions 157 are conversely arranged relative to the main diode 155.

Among the gate runners 130, one that is provided below the first electrode portion 201 is the first runner portion, and one provided below the second electrode portion 202 is the second runner portion. In the example of FIG. 7, the poly runner 133-1 is the first runner portion and the poly runner 133-2 is the second runner portion.

The anode-side Zener diode 210 is provided between the first runner portion 133-1 and the second runner portion 133-2 in the X-axis direction. The anode-side Zener diode 210 of the present example is provided between the anode pad 112 and the poly runner 133-2.

The anode-side Zener diode 210 of the present example has one or more p-type regions 211 and one or more n-type regions 212 that extend in the Y-axis direction. The p-type region 211 and the n-type region 212 may be a polysilicon to which impurities are added. One p-type region 211 has a greater length in the Y-axis direction than the width in the X-axis direction. One n-type region 212 has a greater length in the Y-axis direction than the width in the X-axis direction. The p-type regions 211 and the n-type regions 212 are alternately arrange along the X-axis direction. The p-type region 211 arranged at one end in the X-axis direction is connected to the anode pad 112. The p-type region 211 arranged at the other end in the X-axis direction is connected to the second electrode portion 202. The anode-side Zener diode 210 of the present example includes two p-n junctions having opposite polarities between the anode pad 112 and the second electrode portion 202.

The sixth hole portion 226 and the second hole portion 222 are arranged across the temperature-sensing diode 115 and the anode-side Zener diode 210 in the X-axis direction. The sixth hole portion 226 of the present example is arranged between the poly runner 133-1 and the temperature-sensing diode 115. In addition, the second hole portion 222 is arranged between the poly runner 133-2 and the anode-side Zener diode 210.

As described above, the sixth hole portion 226 may be arranged near the poly runner 133-1, and the second hole portion 222 may be arranged near the poly runner 133-2. For example, the distance between the sixth hole portion 226 and the poly runner 133-1 is smaller than the distance between the sixth hole portion 226 and the temperature-sensing diode 115. In addition, the distance between the second hole portion 222 and the poly runner 133-2 is smaller than the distance between the second hole portion 222 and the anode-side Zener diode 210. Providing the sixth hole portion 226 and the second hole portion 222 can suppress the displacement current crowding at the end portion 135 of the poly runner 133 to suppress dvdt breakdown.

The first hole portion 221 of the present example is arranged between the poly runner 133-1 and the temperature-sensing diode 115 in the X-axis direction. The first hole portion 221 may be arranged near the temperature-sensing diode 115. For example, he distance between the first hole portion 221 and the temperature-sensing diode 115 is smaller than the distance between the first hole portion 221 and the poly runner 133-1. Providing the first hole portion 221 can suppress the displacement current crowding at the end portion 135 of the poly runner 133 to suppress dvdt breakdown. In addition, displacement current crowding at the end portion of the temperature-sensing diode 115 can be suppressed, thereby suppressing dvdt breakdown.

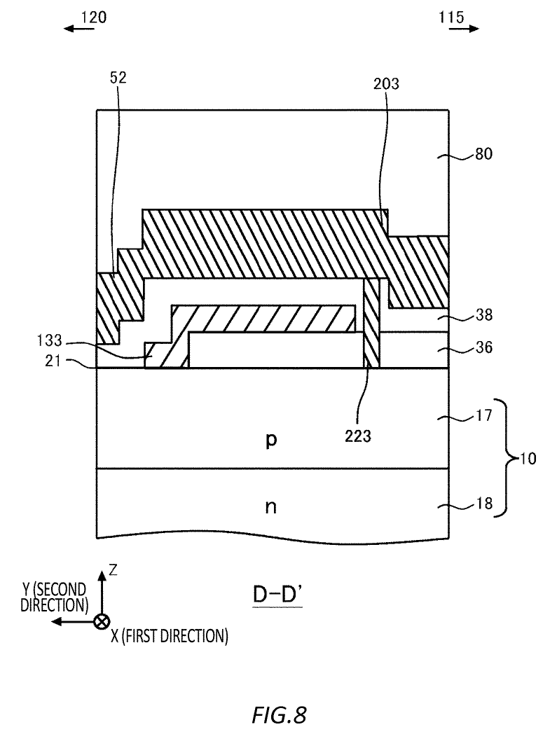

FIG. 8 is a cross-sectional view illustrating an example of a D-D’ line in FIG. 4. D-D’ cross section is a YZ cross section that passes through the third electrode portion 203 and the poly runner 133. Note that, in FIG. 8, the illustration of a lower surface side of the semiconductor substrate 10 is omitted.

The third electrode portion 203 may pass above the poly runner 133, and connect to the source electrode 52 of the active portion 120. The third electrode portion 203 of the present example is connected to the semiconductor substrate 10 through the third hole portion 223 at the temperature-sensing diode 115 side relative to the poly runner 133. In FIG. 8, the positions at which the active portion 120 and the temperature-sensing diode 115 are provided are illustrated with respective arrows.

In the Y-axis direction, the end portion of the field oxide film 36 may be positioned below the poly runner 133. In the Y-axis direction, the end portion of the field oxide film 36 may be covered by the poly runner 133. In this manner, the level difference at the end portion of the field oxide film 36 can be made gentle.

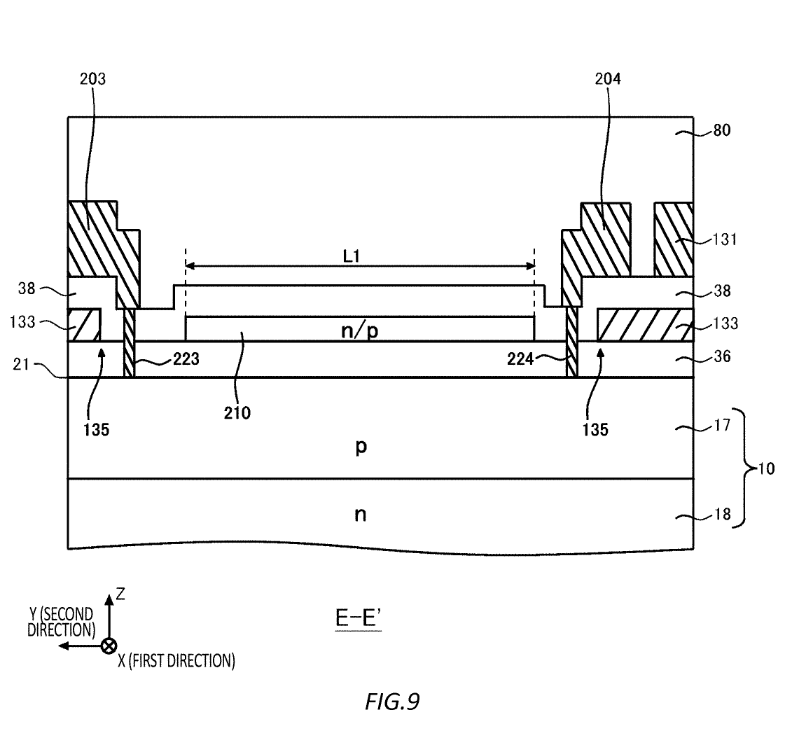

FIG. 9 is a cross-sectional view illustrating an example of E-E’ line in FIG. 4. The E-E’ cross section is a YZ cross section that passes through the anode-side Zener diode 210. The anode-side Zener diode 210 is provided extend by a length L1 in the Y-axis direction. The anode-side Zener diode 210 is arranged between the third hole portion 223 and the fourth hole portion 224 in the Y-axis direction. In this manner, the displacement current that flows in the direction from the poly runner 133 to the anode-side Zener diode 210 can be suppressed, and displacement current crowding at the end portion 135 can be suppressed.

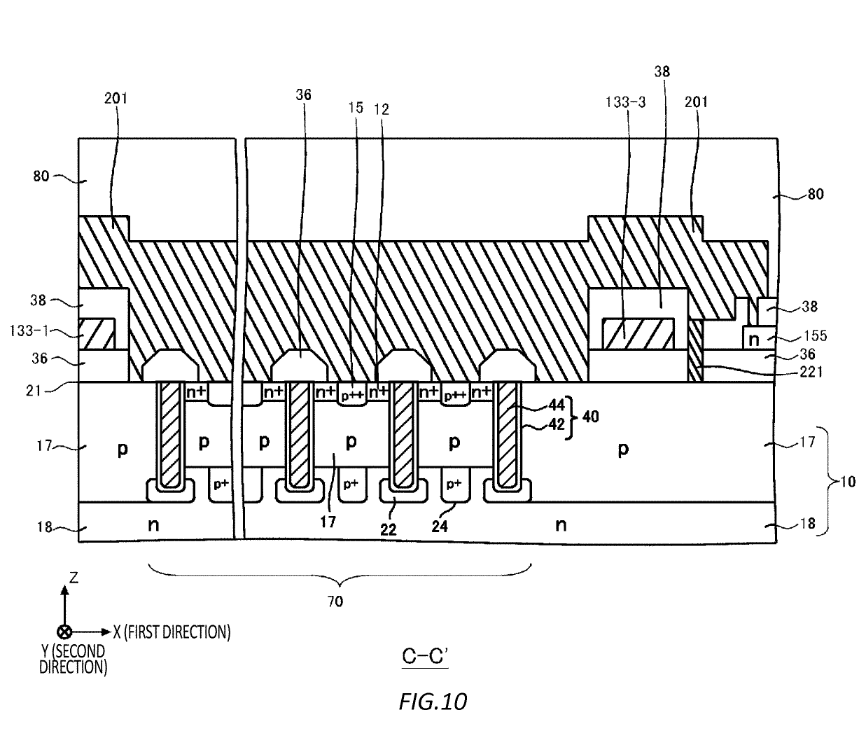

FIG. 10 illustrates another example of the C-C’ cross section. In FIG. 10, among the C-C’ cross sections illustrated in FIG. 7, the region from the first hole portion 221 to the poly runner 133-1 is mainly illustrated. The poly runner 133-1 of the present example is the poly runner 133 extending in the Y-axis direction that is provided between the source electrode 52 and the edge termination structure portion 90 in FIG. 3, for example. In said region, the transistor portion 70 may be provided inside the semiconductor substrate 10 below the first electrode portion 201. The transistor portion 70 may have a same structure as the transistor portion provided in the active portion 120. Through such a structure, the region below the first electrode portion 201 can also function as the active portion 120, and the region of the active portion 120 can be expanded.

In the present example, the sixth hole portion 226 that is illustrated in FIG. 7 is not provided. In the present example, the poly runner 133-3 is provided between the first hole portion 221 and the transistor portion 70 that is provided below the first electrode portion 201. The poly runner 133-1 and the poly runner 133-3 of the present example extend in the Y-axis direction. In addition, the poly runner 133-1 and the poly runner 133-3 are opposite to each other in the X-axis direction across the transistor portion 70 provided below the first electrode portion 201. The present example differs from FIG. 4 in that the poly runner 133-3 is provided between the gate runner 130 (poly runner 133-1) that extends in the Y-axis direction along the edge termination structure portion 90 illustrated in FIG. 4 and the first hole portion 221.

The poly runner 133-1 and the poly runner 133-3 of the present example connect to the gate runner 130 (poly runner 133) that extends in the X-axis direction along the edge termination structure portion 90 illustrated in FIG. 4. Note that, in the present example, the gate runner 130 (poly runner 133) that is provided between the active portion 120 and the first electrode portion 201 illustrated in FIG. 4 is not provided in the region sandwiched by the poly runner 133-1 and the poly runner 133-3.

The poly runner 133-3 of the present example connects to the poly runner 133 provided between the anode pad 112 and the temperature-sensing diode 115, and the active portion 120, illustrated in FIG. 4. In the present example, the first hole portion 221 illustrated in FIG. 4 and the third hole portion 223 and the fourth hole portion 224 may be connected. In the present example, the third hole portion 223 and the fourth hole portion 224 are not provided in the region sandwiched by the poly runner 133-1 and the poly runner 133-3.

The transistor portion 70 includes a gate trench portion 40, a source region 12, the well region 17, and the drift region 18. In the transistor portion 70, a p-type base region having a lower concentration than the well region 17 may be provided instead of the well region 17. The base region may be formed to be shallower than the well region 17.

The gate trench portion 40 is provided from the upper surface 21 for the semiconductor substrate 10 to the inside thereof. The gate trench portion 40 may be provided to extend in the Y-axis direction. The gate trench portion 40 is insulated from the first electrode portion 201 by at least one of the field oxide film 36 or the interlayer dielectric film 38. The gate trench portion 40 is connected to the gate runner 130 in a cross section other than the C-C’ cross section, and a gate voltage is applied thereto.

The gate trench portion 40 of the present example includes a gate conductive portion 44 and a gate dielectric film 42. The gate conductive portion 44 is electrically connected to the gate runner 130, and the gate voltage is applied thereto. The gate conductive portion 44 is formed of polysilicon to which impurities are added, for example. The gate dielectric film 42 insulates the gate conductive portion 44 from the semiconductor substrate 10. The gate dielectric film 42 is an oxide film or a nitride film, for example.

The source region 12 is an n+ type region that is connected to the first electrode portion 201 in the upper surface 21 of the semiconductor substrate 10. The source region 12 may be provided to be in contact with the gate trench portion 40.

The well region 17 is provided between the source region 12 and the drift region 18. The well region 17 is provided to be in contact with the gate trench portion 40. When a predetermined ON voltage is applied to the gate conductive portion 44, the surface layer of the well region 17 that is in contact with the gate trench portion 40 is inverted to become an n-type region, forming a channel. The channel connects the source region 12 and the drift region 18. By forming the channel, a current flows between the source region 12 and the n-type drain region formed on the lower surface of the semiconductor substrate 10. When the transistor portion 70 is an IGBT, a p-type collector region is formed on the lower surface of the semiconductor substrate 10.

The transistor portion 70 may further include at least one of a contact region 15, a lower end region 22, or a high-concentration region 24. The contact region 15 connects to the first electrode portion 201 in the upper surface 21 of the semiconductor substrate 10. Providing the contact region 15 can reduce a contact resistance between the first electrode portion 201 and the semiconductor substrate 10.

The lower end region 22 is a p+ type region that covers a lower end of the gate trench portion 40. Providing the lower end region 22 can reduce electric field strength at the lower end of the gate trench portion 40.

The high-concentration region 24 is a p+ type region provided between two lower end regions 22 in the X-axis direction. Providing the high-concentration region 24 can extend the equipotential line in the X-axis direction, and can reduce the electric field strength at the transistor portion 70.

The transistor portion 70 may be provided for a half or more of the region below the first electrode portion 201 in the top view. The transistor portion 70 may be provided for a half or more or the region below the cathode pad 114. The transistor portion 70 may be provided for half or more of the region between the first hole portion 221 and the poly runner 133-1. Through such a configuration, the surface area of the transistor portion 70 can be expanded, and the surface area of the active portion 120 can be expanded.

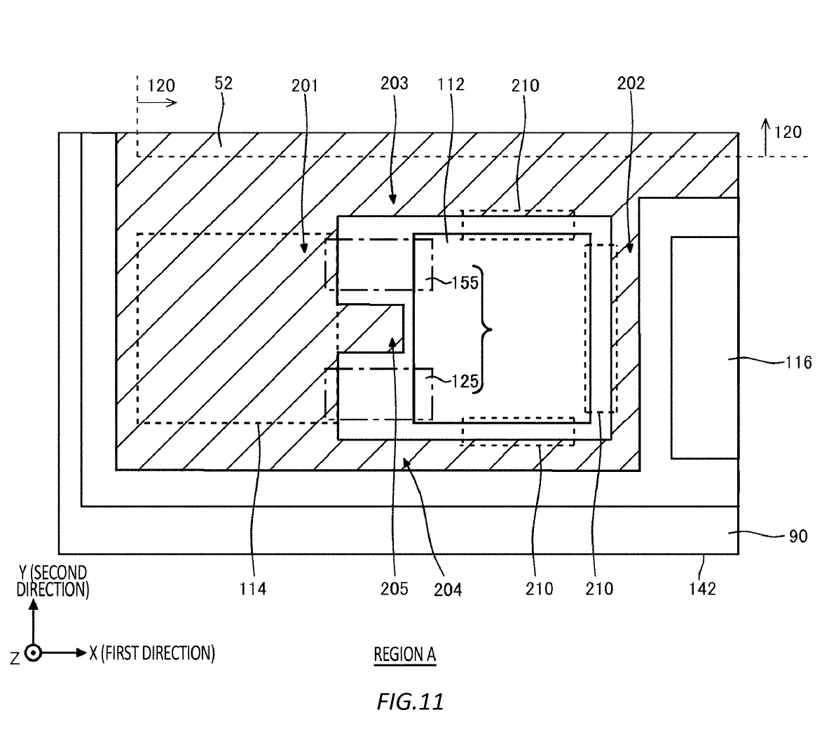

FIG. 11 illustrates another example of the region A. The semiconductor device 100 of the present example differs in the structure of the anode-side Zener diode 210 from the example described for FIGS. 1 to 10. Other structures are similar to those of any of the examples described in FIGS. 1 to 10.

The anode-side Zener diode 210 of the present example is provided to extend along two or more end sides of the anode pad 112. At respective end sides of the anode pad 112, the anode-side Zener diode 210 may be provided over 25% or more of the length of respective end sides. The anode-side Zener diode 210 provided on respective end sides of the anode pad 112 may be provided separately from each other as illustrated in FIG. 11, or may be provided continuously. Through such a configuration, the length of the p-n junction of the anode-side Zener diode 210 can be extended, and the ESD withstand capability of the temperature-sensing diode 115 can be improved.

The anode-side Zener diode 210 may be provided to extend along three end sides of the anode pad 112. The total length of the p-n junction of the anode-side Zener diode 210 may be 300 μm or more, may be 500 μm or more, or may be 700 μm or more.

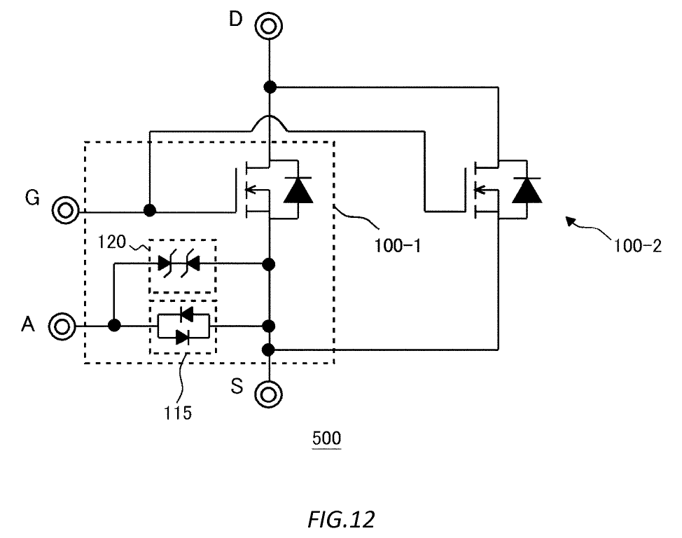

FIG. 12 is a circuit schematic of a semiconductor circuit 500 including the semiconductor device 100. The semiconductor circuit 500 includes a plurality of semiconductor devices 100 connected in parallel. The semiconductor circuit 500 of the present example includes two semiconductor devices 100, namely the a semiconductor device 100-1 and a semiconductor device 100-2 that are connected in parallel.

Among the plurality of semiconductor devices 100, at least one semiconductor device 100 may include the temperature-sensing diode 115 and the anode-side Zener diode 210. The temperature-sensing diode 115 of the present example has its cathode directly connected to a source terminal S and its anode connected to the source terminal S via the anode-side Zener diode 210. Through such a structure, the potential at the anode and the cathode of the temperature-sensing diode 115 can be stabilized.

Among the plurality of semiconductor devices 100, at least one semiconductor device 100 may not include the temperature-sensing diode 115 and the anode-side Zener diode 210. In the present example, the semiconductor device 100-1 includes the temperature-sensing diode 115, and the semiconductor device 100-2 does not include the temperature-sensing diode 115. In this manner, the semiconductor device 100 including the temperature-sensing diode 115 can sense the temperature, while the surface area of the active portion 120 is increased or the chip size is reduced at another semiconductor device 100. Among the plurality of semiconductor devices 100, only one of the semiconductor devices 100 may include the temperature-sensing diode 115.

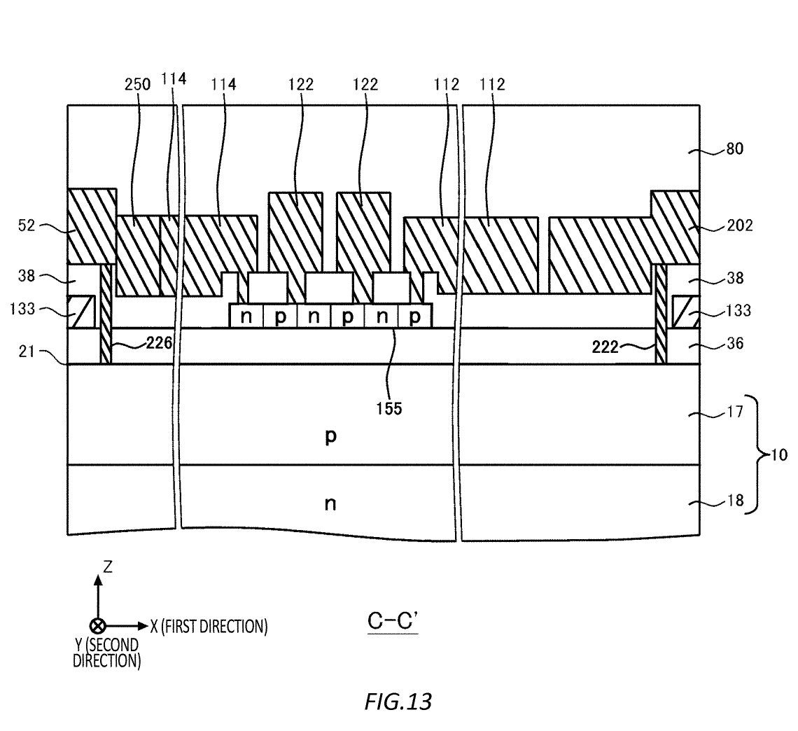

FIG. 13 illustrates another example of the C-C’ cross section. FIG. 13 illustrates a similar range are FIG. 7. In the C-C’ cross section of the present example, the cathode pad 114 is provided instead of the first electrode portion 201. The cathode pad 114 may differ from the source electrode 52 in at least one of the material or the thickness in the Z-axis direction, or they may be the same. The cathode pad 114 and the source electrode 52 may be connected through metal wiring 250. The metal wiring 250 may differ from at least one of the source electrode 52 or the cathode pad 114 in at least one of the material or the thickness in the Z-axis direction, or they may be the same. The metal wiring 250 may differ from the cathode pad 114 in the length in the Y-axis direction, or they may be the same. The cathode pad 114 and the metal wiring 250 may be treated as a part of the source electrode 52.

Although the first hole portion 221 is not provided in the C-C’ cross section of the present example, the first hole portion 221 may be provided. In addition, although the anode-side Zener diode 210 is not provided in the C-C’ cross section of the present example, the anode-side Zener diode 210 may be provided. The structures other than the anode-side Zener diode 210, the first hole portion 221, and the cathode pad 114 are similar to those in the example of FIG. 7.

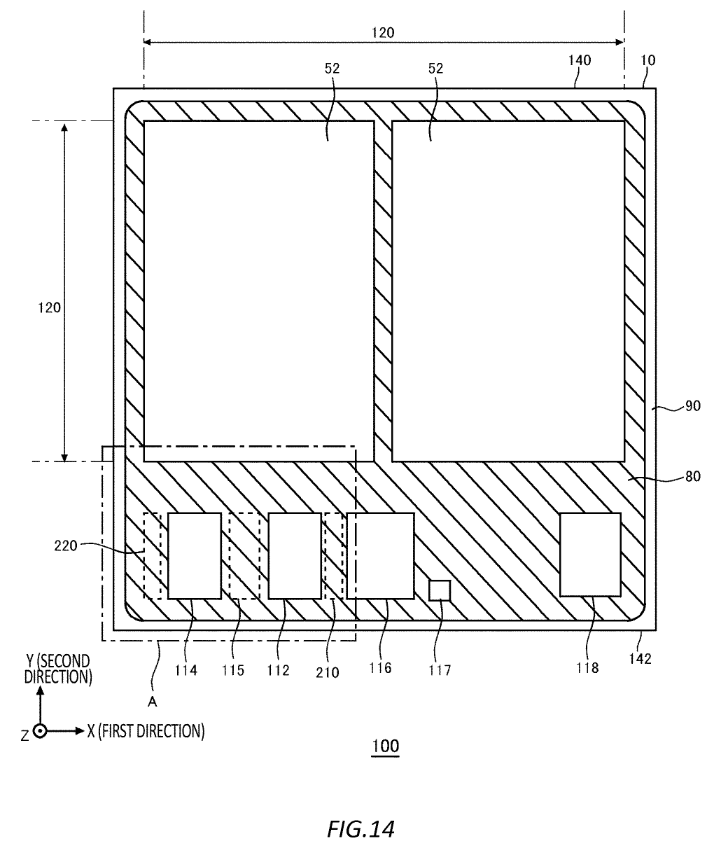

FIG. 14 is a top view illustrating an example of a semiconductor device 100 according to another embodiment. The semiconductor device 100 of the present example includes a cathode-side Zener diode 220. In addition, the cathode pad 114 is a pad that is arranged above the upper surface of the semiconductor substrate 10 and that is separated from the source electrode 52. Other structures are similar to those of any of the examples described in FIGS. 1 to 13.

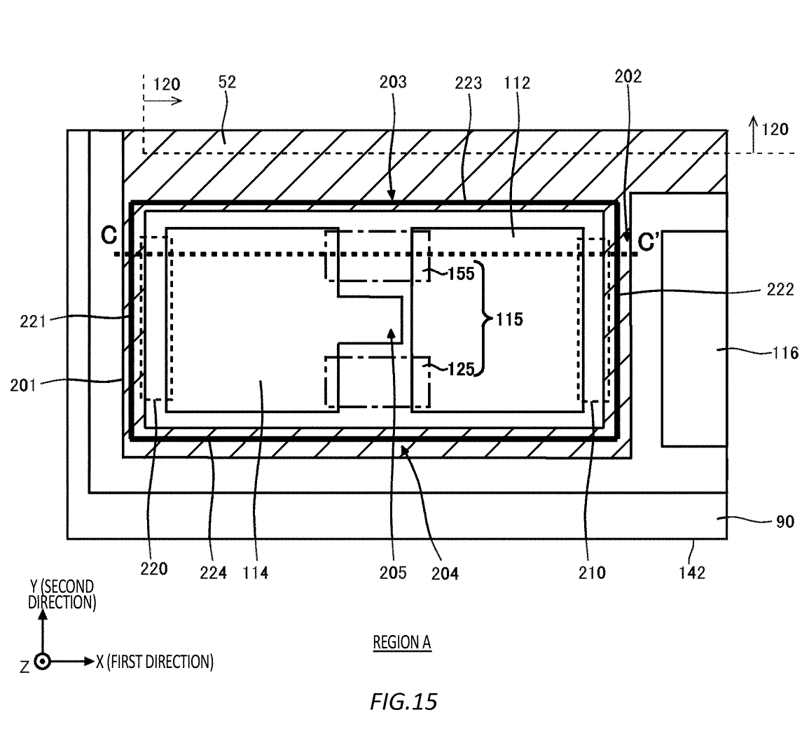

FIG. 15 is an enlarged view of a region A in FIG. 14. As described above, the cathode pad 114 of the present example is separated from the source electrode 52. In the present example, the source electrode 52 that is arranged on the outside relative to the cathode pad 114 in the X-axis direction is the first electrode portion 201. In the present example, the temperature-sensing diode 115 is also arranged between the first electrode portion 201 and the second electrode portion 202. In the present example, the cathode-side Zener diode 220, the cathode pad 114, the anode pad 112, and the anode-side Zener diode 210 are further provided between the first electrode portion 201 and the second electrode portion 202.

The structures of the temperature-sensing diode 115, the anode pad 112, and the anode-side Zener diode 210 are similar to those in any example described for FIGS. 1 to 13. The cathode-side Zener diode 220 is connected to the cathode pad 114 and the first electrode portion 201. Also through the present example, the potential at the cathode of the temperature-sensing diode 115 can be stabilized, and the ESD withstand capability can be improved.

Also in the present example, the first hole portion 221, the second hole portion 222, the third hole portion 223, and the fourth hole portion 224 are provided. The first hole portion 221, the second hole portion 222, the third hole portion 223, and the fourth hole portion 224 surround the cathode pad 114, the cathode-side Zener diode 220, the temperature-sensing diode 115, the anode pad 112, and the anode-side Zener diode 210. In this manner, the displacement current from the gate runner 130 toward the temperature-sensing diode 115 or the like can be suppressed, and dvdt breakdown can be suppressed.

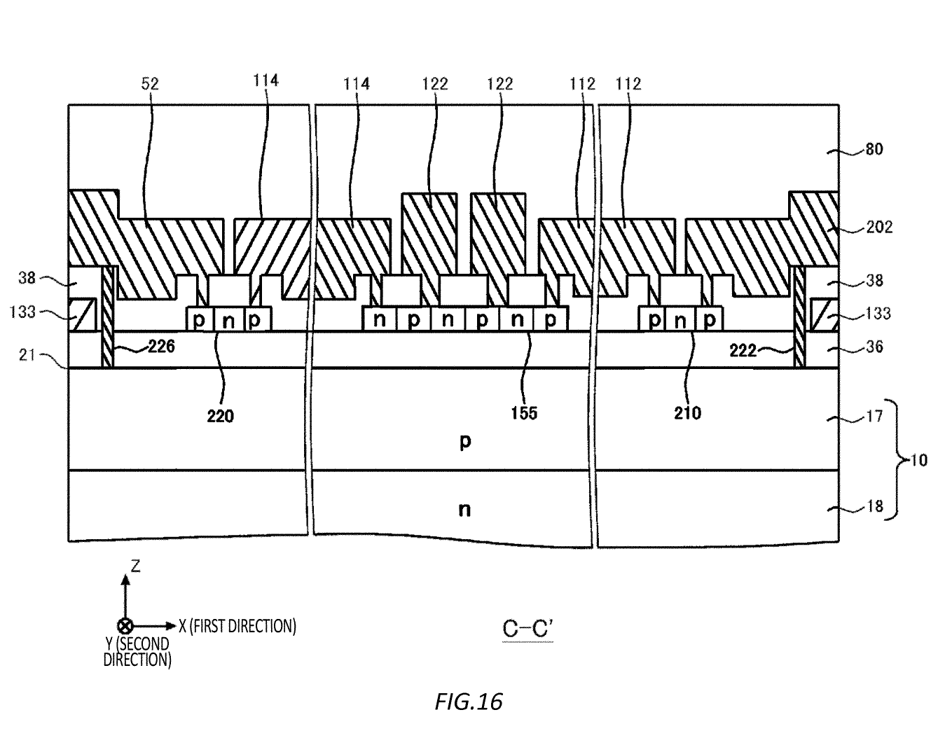

FIG. 16 illustrates an example of a cross section C-C’ in FIG. 15. The A-A’ cross section, the B-B’ cross section, the D-D’ cross section are similar to those in any example described for FIGS. 1 to 13. As described above, the cathode pad 114 is provided to be separated on the interlayer dielectric film 38.

The cathode-side Zener diode 220 has a structure similar to that of the anode-side Zener diode 210. The cathode-side Zener diode 220 is arranged above the upper surface of the semiconductor substrate 10. The cathode-side Zener diode 220 is connected between the cathode pad 114 and the source electrode 52.

The cathode-side Zener diode 220 may be provided to extend in the Y-axis direction. That is, the cathode-side Zener diode 220 may have a greater length in the Y-axis direction than the width in the X-axis direction. The cathode-side Zener diode 220 include one or more p-type portions and one or more n-type portions that form a plurality of p-n junctions. Each of the p-type portions and the n-type portions may have a stripe shape that extends in the Y-axis direction. The p-n junction portion may be arranged along the Y-axis direction.

The length of the cathode-side Zener diode 220 in the Y-axis direction may be 25% or more and 100% or less of the length of the cathode pad 114 in the Y-axis direction. The length of the cathode-side Zener diode 220 may be 50% or more and may be 75% or more of the length of the cathode pad 114. The length of the cathode-side Zener diode 220 may be 300 μm or more, may be 400 μm or more, or may be 500 μm or more. The cathode-side Zener diode 220 may also be provided along two or more end sides of the cathode pad 114, similarly to the anode-side Zener diode 210.

While the present invention has been described by way of the embodiments, the technical scope of the present invention is not limited to the above-described embodiments. It is apparent to persons skilled in the art that various alterations or improvements can be made to the above described embodiments. The above-described embodiments is not limited to a silicon carbide semiconductor substrate, and may be a wide bandgap semiconductor substrate such as a silicon substrate or gallium nitride. It is also apparent from description of the claims that the embodiments to which such modifications or improvements are made may be included in the technical scope of the present invention.

What is claimed is:

1. A semiconductor device comprising:
a semiconductor substrate having an upper surface;
a source electrode that is arranged above the upper surface of the semiconductor substrate and includes a first electrode portion and a second electrode portion;
a temperature-sensing diode having an anode and a cathode, the temperature-sensing diode being arranged between the first electrode portion and the second electrode portion above the upper surface of the semiconductor substrate and having the cathode connected to the first electrode portion;
an anode pad that is arranged between the first electrode portion and the second electrode portion above the upper surface of the semiconductor substrate and connected to the anode of the temperature-sensing diode; and
an anode-side Zener diode that is arranged between the first electrode portion and the second electrode portion above the upper surface of the semiconductor substrate and connected to the anode pad and the second electrode portion.

2. The semiconductor device according to claim 1, wherein
the first electrode portion and the second electrode portion are arranged side by side in a first direction,
in the first direction, the temperature-sensing diode is arranged between the first electrode portion and the anode pad, and
in the first direction, the anode-side Zener diode is arranged between the anode pad and the second electrode portion.

3. The semiconductor device according to claim 2, further comprising:
an interlayer dielectric film that is provided between the source electrode and the semiconductor substrate and in which contact hole that connect the source electrode and the semiconductor substrate are provided,
wherein the contact hole has a first hole portion that connects the first electrode portion and the semiconductor substrate, and
at least a portion of the first hole portion is provided to extend in a second direction that intersects with the first direction.

4. The semiconductor device according to claim 3, wherein
the first hole portion is provided to extend in the second direction over half or more of a width of the temperature-sensing diode in the second direction.

5. The semiconductor device according to claim 3, wherein
the contact hole is provided with a second hole portion that connects the second electrode portion and the semiconductor substrate, and
at least a portion of the second hole portion is provided to extend in a second direction that intersects with the first direction.

6. The semiconductor device according to claim 3, wherein
the temperature-sensing diode has one or more p-type regions and one or more n-type regions that extend in the second direction.

7. The semiconductor device according to claim 6, wherein
the source electrode further includes a third electrode portion and a fourth electrode portion that sandwiches therebetween the temperature-sensing diode in the second direction,
the contact hole has a third hole portion that connects the third electrode portion and the semiconductor substrate and a fourth hole portion that connects the fourth electrode portion and the semiconductor substrate, and
at least a portion of the third hole portion and at least a portion of the fourth hole portion are provided to extend in the first direction.

8. The semiconductor device according to claim 3, wherein
the contact hole surrounds the temperature-sensing diode and the anode-side Zener diode.

9. The semiconductor device according to claim 1, further comprising:
a gate pad arranged above the upper surface of the semiconductor substrate; and
a gate runner that is arranged above the upper surface of the semiconductor substrate and connected to the gate pad,
wherein the gate runner includes a first runner portion provided below the first electrode portion and a second runner portion provided below the second electrode portion, and
the anode-side Zener diode is provided between the first runner portion and the second runner portion.

10. The semiconductor device according to claim 2, further comprising:
a gate pad arranged above the upper surface of the semiconductor substrate; and
a gate runner that is arranged above the upper surface of the semiconductor substrate and connected to the gate pad,
wherein the gate runner includes a first runner portion provided below the first electrode portion and a second runner portion provided below the second electrode portion, and
the anode-side Zener diode is provided between the first runner portion and the second runner portion.

11. The semiconductor device according to claim 3, further comprising:
a gate pad arranged above the upper surface of the semiconductor substrate; and
a gate runner that is arranged above the upper surface of the semiconductor substrate and connected to the gate pad,
wherein the gate runner includes a first runner portion provided below the first electrode portion and a second runner portion provided below the second electrode portion, and
the anode-side Zener diode is provided between the first runner portion and the second runner portion.

12. The semiconductor device according to claim 4, further comprising:
a gate pad arranged above the upper surface of the semiconductor substrate; and
a gate runner that is arranged above the upper surface of the semiconductor substrate and connected to the gate pad,
wherein the gate runner includes a first runner portion provided below the first electrode portion and a second runner portion provided below the second electrode portion, and
the anode-side Zener diode is provided between the first runner portion and the second runner portion.

13. The semiconductor device according to claim 1, further comprising
a transistor portion provided inside the semiconductor substrate below the first electrode portion.

14. The semiconductor device according to claim 2, wherein
the anode-side Zener diode is provided to extend in a second direction that intersects with the first direction.

15. The semiconductor device according to claim 1, wherein
the anode-side Zener diode is provided to extend along two or more end sides of the anode pad.

16. The semiconductor device according to claim 15, wherein
the anode-side Zener diode is provided to extend along three end sides of the anode pad.

17. The semiconductor device according to claim 2, wherein
the anode pad has a first end side facing the second electrode portion, and
a length of the anode-side Zener diode in a second direction that intersects with the first direction is 25% or more and 100% or less of a length of the first end side in the second direction.

18. The semiconductor device according to claim 2, wherein
a length of the anode-side Zener diode in a second direction that intersects with the first direction is 300 μm or more.

19. A semiconductor device comprising:
a semiconductor substrate having an upper surface;
a source electrode that is arranged above the upper surface of the semiconductor substrate and includes a first electrode portion and a second electrode portion;
a temperature-sensing diode having an anode and a cathode, the temperature-sensing diode being arranged between the first electrode portion and the second electrode portion above the upper surface of the semiconductor substrate and having the cathode thereof connected to the first electrode portion;
an anode pad that is arranged between the first electrode portion and the second electrode portion above the upper surface of the semiconductor substrate and connected to the anode of the temperature-sensing diode; and
a transistor portion provided inside the semiconductor substrate below the first electrode portion.

20. A semiconductor device comprising:
a semiconductor substrate having an upper surface;
a source electrode that is arranged above the upper surface of the semiconductor substrate and includes a first electrode portion and a second electrode portion;
a cathode pad that is arranged above the upper surface of the semiconductor substrate and arranged between the first electrode portion and the second electrode portion;
an anode pad that is arranged above the upper surface of the semiconductor substrate and arranged between the cathode pad and the second electrode portion;
a temperature-sensing diode having a cathode connected to the cathode pad and an anode connected to the anode pad, the temperature-sensing diode being arranged between the first electrode portion and the second electrode portion above the upper surface of the semiconductor substrate;
a cathode-side Zener diode that is arranged between the first electrode portion and the second electrode portion above the upper surface of the semiconductor substrate and that is connected to the cathode pad and the first electrode portion; and
an anode-side Zener diode that is arranged between the first electrode portion and the second electrode portion above the upper surface of the semiconductor substrate and that is connected to the anode pad and the second electrode portion.
